(19) United States
(12) Patent Application Publication
(10) Pub. No.: US 2016/0146424 A1
(43) Pub. Date: May 26, 2016

(54) LIGHT-EMITTING DEVICE

(71) Applicants: CHUNGHWA PICTURE TUBES, LTD., Taoyuan County (TW); TATUNG UNIVERSITY, Taipei City (TW)

(72) Inventors: Chuang-Hung CHIU, Hsinchu County (TW); Chao-Heng CHIEN, Taipei City (TW); Jen-Chi LEE, New Taipei City (TW)

(21) Appl. No.: 14/583,201

(22) Filed: Dec. 26, 2014

(30) Foreign Application Priority Data
Nov. 25, 2014 (TW) 103140834

(51) Int. Cl. F21V 5/00

(52) U.S. Cl. CPC F21V 5/002; F21Y 2101/02

(57) ABSTRACT

A light-emitting device includes a light-emitting body and an out-coupling film. The light-emitting body has a light-emitting surface. The out-coupling film is located on the light-emitting surface of the light-emitting body. The out-coupling film includes a substrate, plural first optical micro particles, and plural second optical micro particles. The substrate has a rough surface, and the rough surface faces away from the light-emitting body. The first optical micro particles are uniformly distributed in the substrate, and the index of refraction of the first optical micro particles is about in a range from 2.1 to 2.4. The second optical micro particles are uniformly distributed in the substrate, and the index of refraction of the second optical micro particles is about in a range from 1.7 to 1.9.

### RELATED APPLICATIONS

This application claims priority to Taiwanese Application Serial Number 103140834, filed Nov. 25, 2014, which is herein incorporated by reference.

### BACKGROUND

1. Field of Invention

The present invention relates to a light-emitting device.

2. Description of Related Art

For a typical light-emitting device that utilizes an organic light-emitting diode (OLED) as a light source, an out-coupling film may be adhered to a surface of the OLED to increase the brightness of the light-emitting device.

Since the index of refraction of the out-coupling film is very different from the index of refraction of the OLEO, when the OLED emits light, total reflection usually occurs in the OLED, and also for a portion of the light at a surface of the out-coupling film in contact with air. The totally reflected light of the OLED and the out-coupling film cannot irradiate out, which makes the illuminance and the brightness of the light-emitting device difficultly to be improved.

In addition, although a micro structure or a lens structure may be used on the surface of the out-coupling film to reflect or refract the light, the manufacturing cost al the light-emitting device is thus increased and the surface of the out-coupling film that faces the OLED becomes uneven due to these additional structures. Also, a gap is usually formed between the out-coupling film and the OLED, which makes the light-emitting efficiency of the light-emitting device difficult to be improved.

### SUMMARY

An aspect of the present invention is to provide a light-emitting device.

According to an embodiment of the present invention, a light-emitting device includes a light-emitting body and an out-coupling film. The light-emitting body has a light-emitting surface. The out-coupling film is located on the light-emitting surface of the light-emitting body. The out-coupling film includes a substrate, plural first optical micro particles, and plural second optical micro particles. The substrate has a rough surface, and the rough surface faces away from the light-emitting body. The first optical micro particles are uniformly distributed in the substrate, and the index of refraction of the first optical micro particles is about in a range from 2.1 to 2.4. The second optical micro particles are uniformly distributed in the substrate, and the index of refraction of the second optical micro particles is about in a range from 1.7 to 1.9.

In one embodiment of the present invention, the first optical micro particles are made of a material including lanthanum oxides.

In one embodiment of the present invention, the first optical micro particles are made of a material including group IIB metal sulfides.

In one embodiment of the present invention, the second optical micro particles are made of a material including lanthanum oxides.

In one embodiment of the present invention, the second optical micro particles are made of a material including group IIA metal oxides.

In one embodiment of the present invention, the rough surface of the substrate has at least one protruding portion and at least one concave portion, and a perpendicular distance between the protruding portion and the concave portion is about in a range from 5 μm to 10 μm.

In one embodiment of the present invention, the thickness of the substrate is about in a range from 150 μm to 250 μm or in a range from 350 μm to 450 μm.

In one embodiment of the present invention, the first and second optical micro panicles are about in a range from 1% to 3% by weight of the out-coupling film.

In one embodiment of the present invention, the light-emitting device further includes an optical adhesive. The optical adhesive is between the out-coupling film and the light-emitting surface of the light-emitting body. The index of refraction of the optical adhesive, the index of refraction of the light-emitting body, and the index of refraction of the substrate are about in a range from 12 to 1.8.

In one embodiment of the present invention, the substrate is made of a material including polydimethylsilaxane (PDMS).

In the aforementioned embodiments of the present invention, the substrate has the rough surface, and the first and second optical micro particles are uniformly distributed in the substrate. Therefore, when the light-emitting body emits light, light not only may be directly refracted in an outward direction by the rough surface, but also may be reflected and refracted by the first and second optical micro particles to thereafter irradiate in an outward direction from the rough surface. The first and second optical micro particles, and the rough surface of the substrate may effectively reduce the probability of total reflection phenomenon with respect to light in the OLED, thereby improving the light-emitting efficiency, the illuminance, and the brightness of the light-emitting device.

### BRIEF DESCRIPTION OF THE DRAWINGS

The invention can be more fully understood by reading the following detailed description of the embodiments, with reference made to the accompanying drawings as follows:

FIG. 1 is a perspective view of a light-emitting device according to one embodiment of the present invention;

FIG. 2 is a cross-sectional view of he light-emitting device taken along line 2-2 shown in FIG. 1;

FIG. 3 is a schematic view of another light path in the light-emitting device shown in FIG. 2;

FIG. 4 is a schematic view of another light path in the light-emitting device shown in FIGS. 2; and

FIG. 5 is a perspective view of a light-emitting device according to one embodiment of the present invention.

### DETAILED DESCRIPTION

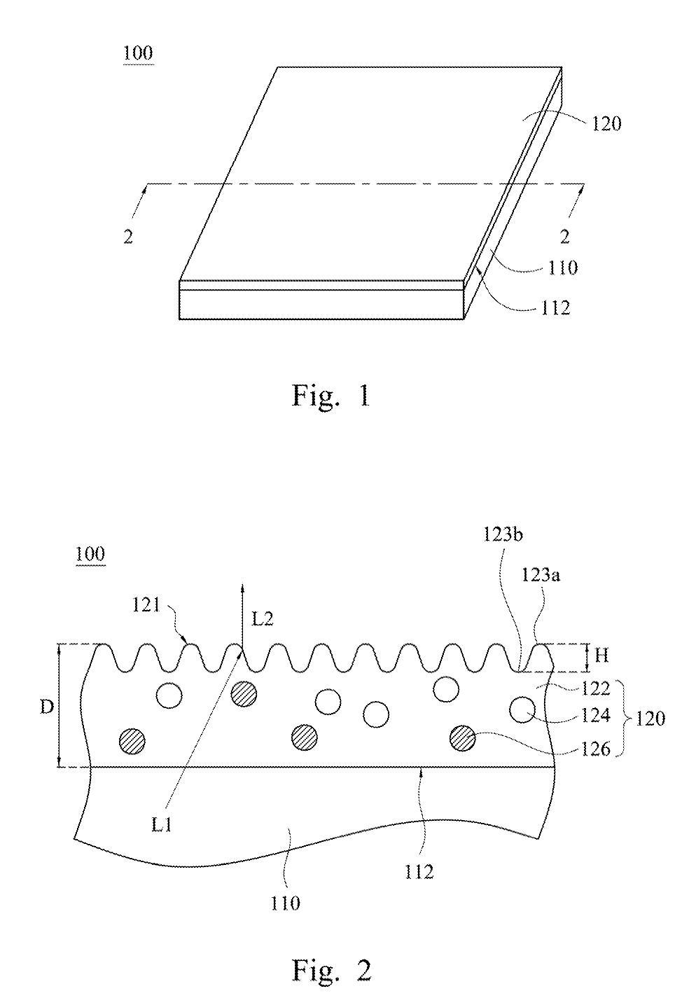

As shown in FIG. 1 and FIG. 2, a light-emitting device 100 includes a light-emitting body 110 and an out-coupling film 120. The light-emitting body 110 has a light-emitting surface 112. The out-coupling film 120 is located on the light-emitting surface 112 of the light-emitting body 110. The out-coupling film 120 includes a substrate 122, plural first optical micro particles 124, and plural second optical micro particles 126. The substrate 122 has a rough surface 121, and the rough surface 121 of the substrate 122 faces away from the light-emitting body 110. The first optical micro particles 124 are uniformly distributed in the substrate 122, and the index of refraction of the first optical micro particles 124 is about in a range from 2.1 to 2.4. “About” is used herein to refer to the fact that there may be 5% difference. The second optical micro particles 126 are uniformly distributed in the substrate 122, and the index of refraction of the second optical micro particles 126 is about in a range from 1.7 to 1.9

In this embodiment, the first optical micro particles 124 may be made of a material including lanthanum oxides, such as cerium oxide with the index of refraction 2.2. The first optical micro particles 124 may also be made of a material including group IIB metal sulfides, such as zinc sulfide with the index of refraction 2.4, and cadmium sulfide with the index of refraction 2.35. The second optical micro particles 126 may be made of a material including lanthanum oxides, such as gadolinium oxide with the index of refraction 1.8, and neodymium oxide with the index of refraction 1.8. The second optical micro particles 126 may also be made of a material including group IIA metal oxides, such as beryllium oxide with the index of refraction 1.7, magnesium oxide with the index of refraction 1.7, calcium oxide with the index of refraction 1.8, and barium oxide with the index of refraction 1.9. Moreover, the color of the first and second optical micro particles 124, 126 may be transparent white. In addition, the first and second optical micro particles 124, 126 may be about in a range from 1% to 3% by weight of the out-coupling film 120.

The light-emitting body 110 may be an organic light-emitting diode (OLEO), and the index of refraction of the light-emitting body 110 is about 1.5. The substrate 122 may be made of a material including polydimethylsiloxane (PDMS), such that the index of refraction of the substrate 122 is also about 1.5. As a result, the index of refraction of the substrate 122 and the index of refraction of the light-emitting body 110 may be substantially the same. For example, the index of refraction of the substrate 122 and the index of refraction of the light-emitting body 110 are in a range from 1.2 to 1.8. When the light-emitting body 110 emits light, light L1 may irradiate outwards from the light-emitting surface 112 of the light emitting body 110 and completely enter the out-coupling film 120, so that total reflection in the light-emitting body 110 is not prone to occur. That is to say, the substrate 122 made of PDMS may improve the light-emitting efficiency of the light emitting body 110.

The rough surface 121 of the substrate 122 has at least one protruding portion 123a and at least one concave portion 123b, and a perpendicular distance H between the protruding portion 123a and the concave portion 123b is about in a range from 5 μm to 10 μm. The perpendicular distance H may be referred to as a roughening height. When the light L1 is transmitted to the rough surface 121 of the substrate 122, refracted light L2 may be formed at the rough surface 121 due to the index of refraction of the substrate 122 is different from that of air. Since the substrate 122 has the uneven rough surface 121, the probability of total reflection phenomenon with respect to light in the out-coupling film 120 may be reduced. As a result, light may be effectively transmitted outwards the light-emitting device 100, thereby improving the light-emitting efficiency, the illuminance, and the brightness of the light-emitting device 100.

Furthermore, the thickness D of the substrate 122 is about in a range from 150 μm to 250 μm or in a range from 350 μm to 450 μm, and the transmittance of the substrate 122 is greater than or equal to 95% due to the material property of PDMS. The substrate 122 of the out-coupling film 120 has thin thickness and high transmittance, and therefore it is beneficial for light transmission and miniaturized design of the light-emitting device 100.

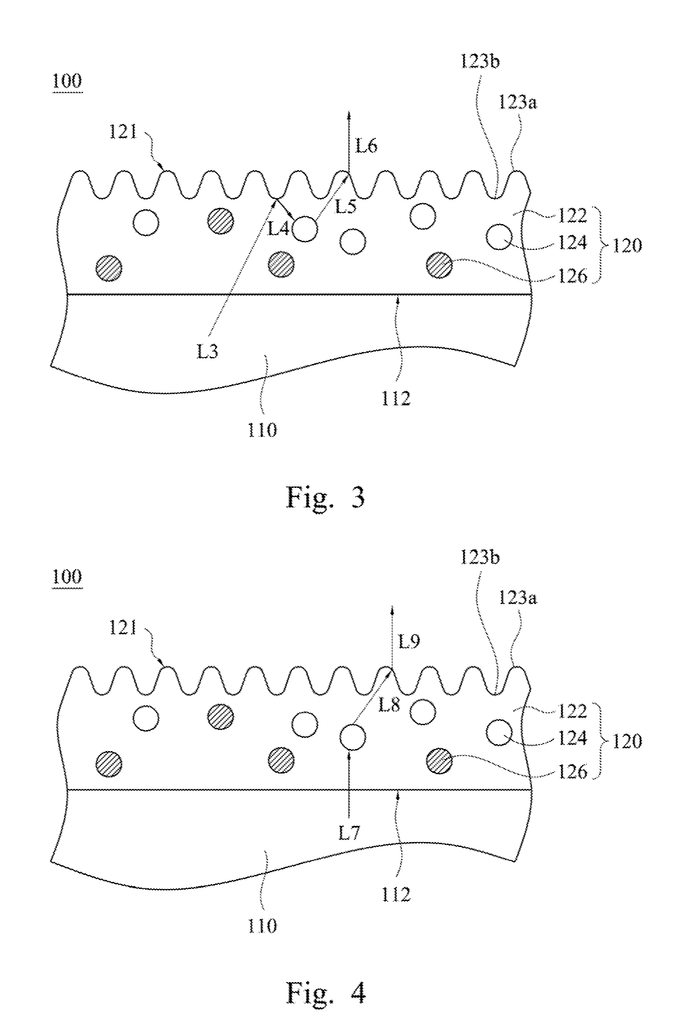

FIG. 3 is a schematic view of another light path in the light-emitting device 100 shown in FIG. 2. The first and second optical micro particles 124, 126 uniformly distributed in the substrate 122 may be used to reflect light in the out-coupling film 120. For example, when the light-emitting body 110 emits light, light L3 is transmitted to the rough surface 121 of the substrate 122 from the light-emitting surface 112 of the light emitting body 110. Although the rough surface 121 may reflect the light L3 to form light L4, the light L4 may be reflected by the first optical micro particles 124 to form light L5. Next, the light L5 may be refracted by the rough surface 121 of the substrate 122, such that light L6 is formed to irradiate in an outward direction.

FIG. 4 is a schematic view of another light path in the light-emitting device 100 shown in FIG. 2. The first and second optical micro particles 124, 126 are uniformly distributed in the substrate 122 to refract light in the out-coupling film 120. For example, when the light emitting body 110 emits light, light L7 is transmitted to the first optical micro particle 124 from the light-emitting surface 112 of the light-emitting body 110. The first optical micro particle 124 may refract the light L7 to form light L8. Thereafter, the light L8 may be refracted by the rough surface 121 of the substrate 122, such that light L9 is formed to irradiate in an outward direction.

As shown in FIG. 3 and FIG. 4, light in the out-coupling film 120 not only may be reflected and refracted by the first optical micro particles 124, but also may be reflected and refracted by the second optical micro particles 126. Since the index of refraction of the first optical micro particles 124 is about in a range from 2.1 to 2.4 and the index of refraction of the second optical micro particles 126 is about in a range from 1.7 to 1.9, different index of refraction of the first and second optical micro particles 124, 126 can effectively transmit light of the light-emitting body 110 to the outside of the light-emitting device 100.

The substrate 122 has the rough surface 121, and the first and second optical micro particles 125, 126 are uniformly distributed in the substrate 122. Therefore, when the light-emitting body 110 emits light, light not only may be directly refracted in an outward direction by the rough surface 121, but also may be reflected and refracted by the first and second optical micro particles 124, 126 to thereafter irradiate in an outward direction from the rough surface 121. The first and second optical micro particles 124, 126 in the substrate 122, and the rough surface 121 of the substrate 122 may effectively reduce the phenomenon of total reflection with respect to light in the light-emitting device 100, thereby improving the light-emitting efficiency, the illuminance, and the brightness of the light-emitting device 100. Compared with the light-emitting device 100 of the present invention and the light-emitting body 110 without the out-coupling film 120, the brightness of the light--emitting device 100 may be substantially improved more than or equal to 81%. Hence, the light-emitting device 100 has good product competitiveness.

Moreover, it is more flexible for the design of the light-emitting device 100 due to the out-coupling film 120. For example, designers may select the light-emitting body 110 that has low illuminance and brightness and dispose the out-coupling film 120 on the light-emitting body 110, such that the illuminance and the brightness of the entire light-emitting device 100 may be improved, and the cost of the light-emitting device 100 is reduced. In addition, the light-emitting device 100 has the out-coupling film 120, so that designers may reduce the output power of the light-emitting body 110 to extend the lifespan of the light-emitting body 110.

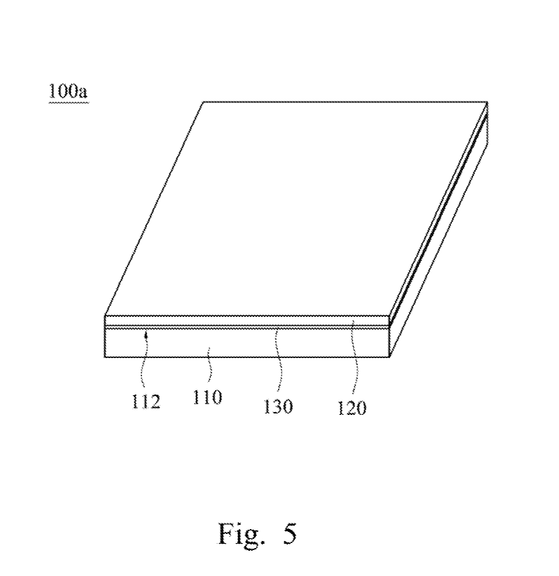

In this embodiment, the material of the out-coupling film 120 is self-adhesive, such that the out-coupling film 120 may be directly stacked on the light-emitting body 110. However, in another embodiment, the out-coupling film 120 may also be adhered to the light-emitting body 110 by utilizing an optical adhesive, as shown in FIG. 5. In the following description, other types of light-emitting devices will be described. It is to be noted that the connection relationships and the materials of the elements described above will not be repeated in the following description.

FIG. 5 is a perspective view of a light-emitting device 100a according to one embodiment of the present invention. The light-emitting device 100a includes the light-emitting body 110 and the out-coupling film 120. The difference between this embodiment and the embodiment shown in FIG. 1 is that the light-emitting device 100a further includes an optical adhesive 130. The optical adhesive 130 is between the out-coupling film 120 and the light-emitting surface 112 of the light-emitting body 110, such that the out-coupling film 120 may be firmly adhered to the light-emitting surface 112 of the light-emitting body 110. The optical adhesive 130 may prevent forming bubbles between the out-coupling film 120 and the light-emitting surface 112 of the light-emitting body 110, thereby improving the light-emitting efficiency of the light-emitting device 100a.

In this embodiment, the index of refraction of the optical adhesive 130, the index of refraction of the light-emitting body 110, and the index of refraction of the substrate of the out-coupling film 120 are substantially the same (e.g., about in a range from 1.2 to 1.8). Therefore, the light-emitting efficiency, the illuminance, and the brightness of the light-emitting device 100a may be improved. Moreover, the transmittance of the optical adhesive 130 may be greater than or equal to 95%, and such design is beneficial for light transmission.

In the following description, the manufacturing method of the out-coupling film 120 shown in FIG. 2 will be described.

First of all, a soft macromolecular polymer material and a curing agent are placed into a suitable solution to form a mixed solution. In this embodiment, the macromolecular polymer material may be PDMS. The suitable solution may be tetrahydrofuran (THF) or dimethylformamide (DMF). The weight ratio of PDMS to the curing agent is about 10:1. Thereafter, first optical micro particles with the index of refraction about in a range from 2.1 to 2.4 and second optical micro particles with the index of refraction about in a range from 1.7 to 1.9 ore mixed with the solution depending on measurement,, and the mixed solution is stirred, such that the first and second optical micro particles are uniformly distributed in the solution. In this embodiment, the first and second optical micro particles are in a range from 1% to 3% by weight of an out-coupling film.

In the next step, the solution having the first and second optical micro particles may be placed in a vacuum environment (e.g., 30 minutes) to draw out bubbles in the solution. Thereafter, a plate having a printed uneven surface structure may be cleaned by acetone, alcohol, and pure water, and nitrogen is used to dry the plate. After the aforesaid vacuum treatment for the solution is finished, the solution may be poured on the plate that has the uneven surface structure, and a spin coater is used to control the rotation speed of the plate, such that the solution is uniformly distributed on the plate. The plate is located on the table of the spin coater. The plate may be made of a material including glass, and the area of the plate is substantially the same as that of a light-emitting body (e.g., an OLED) that is awaiting the adhesion of an out-coupling film.

In the next step, the plate filled with the solution is placed in a vacuum environment (e.g., 30 minutes) to draw out bubbles in the solution. Afterwards, the solution is baked to solidify. The baking temperature may be 75° C., and the baking time may be 1 hour, but the present invention is not limited in this regard.

After the solution is baked and solidified to form a thin film, the thin film is separated from the plate. When the rotation speed of the spin coater is about in a range from 400 rpm to 500 rpm, the thickness of the solidified thin film is about in a range from 350 μm to 450 μm. When the rotation speed of the spin coater is about in a range from 600 rpm to 800 rpm, the thickness of the solidified thin film is about in a range from 150 μm to 250 μm. The solidified thin film may be the out-coupling film 120 shown in FIG. 2. In this embodiment, the solidified thin film may be evenly adhered to a light-emitting body by utilizing the adhesion of the material of the thin film, such that the light-emitting device 100 shown in FIG. 1 is obtained. Moreover, an optical adhesive is evenly adhered to the light-emitting body. Thereafter, the solidified thin film is adhered to the optical adhesive, such that the light-emitting device 100a shown in FIG. 5 is obtained.

What is claimed is:

1. A light-emitting device, comprising:
a light-emitting body having a light-emitting surface; and
an out-coupling film located on the light-emitting surface of the light-emitting body and comprising:
a substrate having a rough surface that faces away from the light-emitting body;
a plurality of first optical micro particles uniformly distributed in the substrate, wherein the index of refraction of the first optical micro particles is about in a range from 2.1 to 2.4; and
a plurality of second optical micro particles uniformly distributed in the substrate, wherein the index of refraction of the second optical micro particles is about in a range from 1.7 to 1.9.

2. The light-emitting device of claim 1 wherein the first optical micro particles are made of a material comprising lanthanum oxides.

3. The light-emitting device of claim 1 wherein the first optical micro particles are made of a material comprising group IIB metal sulfides.

4. The light-emitting device of claim 1, wherein the second optical micro particles are made of a material comprising lanthanum oxides.

5. The light-emitting device of claim 1, wherein the second optical micro particles are made of a material comprising group IIA metal oxides.

6. The light-emitting device of claim 1, wherein the rough surface of the substrate has at least one protruding portion and at least one concave portion, and a perpendicular distance between the protruding portion and the concave portion is about in a range from 5 μm to 10 μm.

7. The light-emitting device of claim 1, wherein the thickness of the substrate is about in a range from 150 μm to 250 μm or in a range from 350 μm to 450 μm.

8. The light-emitting device of claim 1, wherein the first and second optical micro particles are about in a range from 1% to 3% by weight of the out-coupling film.

9. The light-emitting device of claim 1, further comprising:
an optical adhesive between the out-coupling film and the light-emitting surface of the light-emitting body, wherein the index of refraction of the optical adhesive, the index of refraction of the light-emitting body, and the index of refraction of the substrate are about in a range from 1.2 to 1.8.

10. The light-emitting device of claim 1, wherein the substrate is made of a material comprising polydimethylsiloxane (PDMS).
